(19) United States
(12) Patent Application Publication
(10) Pub. No.: US 2007/0188186 A1
(43) Pub. Date: Aug. 16, 2007

(54) Systems and methods for managing power supplied to integrated circuits

(75) Inventor: Naoki Kiryu, Tokyo (JP)

Correspondence Address: LAW OFFICES OF MARK L. BERRIER, 3811 BEE CAVES ROAD, SUITE 204, AUSTIN, TX, 78746, US

(73) Assignee: Toshiba America Electronic Components

(21) Appl. No.: 11/353,514

(22) Filed: Feb. 14, 2006

(51) Int. Cl. H03K 19/003

(52) U.S. Cl. 326/10; 326/41

(57) ABSTRACT

Systems and methods for reducing power consumed by digital circuits using an off-chip controller to selectively provide power to individual portions of the circuitry. One embodiment comprises an IC and an off-chip power controller. The circuitry constructed on the IC chip includes two or more independently powered regions. The power controller is configured to selectively power on (or off) each of the regions. The regions that are powered off have no leakage current, and therefore eliminate power use. In one embodiment, the regions comprise SPE's in a multiprocessor. The power controller may be configured to provide power to the SPE's at different voltages. The power controller may identify the SPE's to be powered on and off in various ways, such as reading a memory that stores the information, and may provide/inhibit power to each SPE in various ways, such as switching relays that couple the SPE's to a power source.

### BACKGROUND

1. Field of the Invention

The invention relates generally to the operation of electronic circuits, and more particularly to systems and methods for managing and controlling the power supplied to different regions within integrated circuits (IC's).

2. Related Art

Digital devices are becoming increasingly complex. The devices are operated at ever-increasing rates, resulting in corresponding increases in the power requirements of the devices and the amounts of heat that are dissipated by the devices. Also, as the complexity of these devices increases, there are more and more opportunities for manufacturing defects to occur, thereby impairing or impeding the proper operation of the devices. Addressing these issues is becoming increasingly important.

Traditionally, when it is desired to reduce power consumption in an IC, the clock rate for the IC is reduced. When the clock rate is reduced, the number of operations performed by the device in a given amount of time likewise decrease. Since a reduced number of operations are performed, a reduced amount of power is used. Similarly, a reduced amount of heat is generated in the IC. The clock rate is reduced for an entire IC.

While reducing the clock rate for the entire IC may be effective in reducing the power consumption and heat generation of the IC, this also reduces the amount of work that is performed by the IC. It may be more efficient to maintain the normal clock rate for most of the IC while inhibiting the clock signal to parts of the IC that are not needed. This allows more operations to be performed by the IC than if the clock rate for the entire IC is reduced, while still saving power and reducing heat generation.

Although inhibiting the clock signal to parts of the IC that are not needed reduces the amount of power required by the IC, there is still leakage current in the unused parts of the IC. As a result, these parts of the IC still use some amount of power (albeit a reduced amount), and generate a corresponding amount of heat that must be dissipated. It would therefore be desirable to provide means to further reduce the power consumption and heat generation in these unused parts of the IC.

As noted above, the increasing complexity of IC's results not only in increased power consumption and heat generation, but also in increased opportunities for defects to arise in the IC's. These defects can cause the IC's to malfunction or have reduced performance. Ultimately, this results in reduced yields for the IC's. These issues can in some instances be addressed using the same techniques described above to reduce power in the IC's.

For example, an IC that malfunctions at the normal clock rate may not malfunction when operated at a reduced clock rate. Reducing the clock rate for the IC therefore reduces power consumption and also prevents malfunctions in the IC. This solution, however, results in reduced operational capacity. In another example, an IC may have redundant, identical functional blocks—if one of the functional blocks has a defect that causes it to malfunction, the clock signal to the malfunctioning block may be inhibited, thereby preventing the functional block from causing errors in the operation of the IC, as well as reducing the power used by the functional block. As noted above, however, leakage currents continue to use power in the disabled functional block.

It would therefore be desirable to provide means for avoiding malfunctions and reduced performance that further reduce the power consumption and heat generation in the IC, in comparison to conventional means. It would also be desirable to provide these means in such a way as to improve the manufacturing yield of the IC.

### SUMMARY OF THE INVENTION

One or more of the problems outlined above may be solved by the various embodiments of the invention. Broadly speaking, the invention comprises systems and methods for reducing power consumed by digital circuits using an off-chip controller to selectively provide power to individual portions of the circuitry.

In one embodiment, the circuitry of a target circuit is subdivided into independently powered regions/blocks. The voltage and/or current supplied to each region/block can then be controlled as necessary by the attached/connected controller through an appropriately arranged set of ports coupling the controller to each region.

The invention may be implemented in a variety of ways, and various exemplary embodiments will be described in detail below. One embodiment comprises a system including an integrated circuit and an off-chip power controller. The circuitry constructed on the integrated circuit chip includes two or more regions that are independently powered. The off-chip power controller is coupled to each of these regions of the circuitry. The power controller is configured to selectively power on (or off) each of the regions of the circuitry. The regions of the circuitry that are powered off use no power, and therefore improve the power efficiency of the system in comparison to systems in which unused regions of the circuitry receive no clock signal, but remain powered on and consequently experience leakage currents that expend power.

In one embodiment, the independently powered regions of the circuitry comprise functional blocks, such as processor cores in a microprocessor. The power controller may be configured not only to selectively power the different regions on/off, but also to provide power to the different regions at different voltages. The power controller may be configured to identify the regions to be powered on (and those to be powered off) in various ways, such as reading a memory that stores the information. The memory may be part of the power controller or part of the on-chip circuitry. The power controller may also provide or inhibit power to each region of the on-chip circuitry in various ways, such as switching relays that couple the regions to a power source.

Another embodiment comprises a method that includes generating one or more control signals in an off-chip power controller and providing or inhibiting power to different regions of the circuitry on an integrated circuit chip according to the control signals. In one embodiment, the control signals define a first set of regions of circuitry on an integrated circuit chip to be powered on and a second set of regions of circuitry on the integrated circuit chip to be powered off. These signals may be used to control relays or other means for coupling the different regions of the circuitry to a power source. The control signals may be generated after reading a memory (on-chip or off-chip) to determine which of the regions of the on-chip circuitry should be powered on and which should be powered off.

Another embodiment comprises a method implemented in an integrated circuit having multiple functional blocks, wherein one or more of the functional blocks are redundant. First, it is determined whether any of the redundant functional blocks are defective. If any of the redundant functional blocks are determined to be defective, no power is provided to these functional blocks. Power is provided to the remainder of the functional blocks, and the integrated circuit is operated with those functional blocks to which power is provided. The power controller is constructed off-chip from the integrated circuit in order to allow additional, redundant functional blocks to be constructed on-chip. By providing additional, redundant functional blocks on the chip, the likelihood of being able to replace a defective functional block with one of the redundant functional blocks increases, thereby increasing the yield for the integrated circuit.

Numerous additional embodiments are also possible.

The various embodiments of the invention may provide a number of advantages over prior art systems and methods. For example, by inhibiting power to selected regions (e.g., functional block) of an integrated circuit, embodiments of the present invention can eliminate leakage current that occurs in prior art systems that inhibit clock signals to selected regions, but do not power them down. Other embodiments can improve yields in integrated circuits by allowing the integrated circuits to be designed with additional, redundant functional blocks that can be used as replacements for defective functional blocks (which can be selectively powered down.) Still other advantages will be apparent to those of skill in the art of the invention.

### BRIEF DESCRIPTION OF THE DRAWINGS

Other objects and advantages of the invention may become apparent upon reading the following detailed description and upon reference to the accompanying drawings.

FIG. 1 is a functional block diagram illustrating the layout of a system in accordance with one embodiment.

FIG. 2 is a flow diagram illustrating operations in accordance with one embodiment.

FIG. 3 is a functional block diagram illustrating the layout of a system in accordance with one embodiment.

FIG. 4 is a flow diagram illustrating operations in accordance with one embodiment.

FIG. 5 is a diagram illustrating an increase in yield versus the number of defective SPE's which are acceptable in accordance with one embodiment.

While the invention is subject to various modifications and alternative forms, specific embodiments thereof are shown by way of example in the drawings and the accompanying detailed description. It should be understood, however, that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF EXEMPLARY EMBODIMENTS

One or more embodiments of the invention are described below. It should be noted that these and any other embodiments described below are exemplary and are intended to be illustrative of the invention rather than limiting. As described herein, various embodiments of the invention comprise systems and methods associated with integrated circuits to manage power consumption and accommodate underperforming or otherwise defective logic circuits by using an off-chip PMU to selectively provide or inhibit power to different regions (e.g., functional blocks) within the integrated circuits. In one embodiment, an off-chip power management unit (PMU) is used to control the power delivered to different regions/blocks of the circuitry within an IC. The PMU is configured to selectively provide power to the different regions of the circuitry within the IC. The PMU may completely shut off power to one or more of the different regions of the circuitry, thereby eliminating leakage currents and associated power consumption.

In this embodiment, the IC is a multiprocessor. The multiprocessor includes multiple processor cores or subprocessor elements (SPE's) and ancillary elements. Each of the SPE's in this embodiment comprises one of the independently powered regions of the integrated circuit. Consequently, power can be provided to some SPE's, while no power is provided to other SPE's. When a particular SPE is defective or unneeded, power to that SPE is shut off by the PMU.

The PMU controls the power to each SPE using relays that are coupled between each of the SPE's and a power source. The PMU determines which of the SPE's are to be powered on and which are to be powered off by, for example, reading a memory that is configured to store this information. In one embodiment, this is done when the system boots up. After the PMU determines which of the SPE's are supposed to receive power, the PMU closes the relays between these SPE's and the power source. The relays between the SPE's that are to be powered off are opened by the PMU to inhibit power to those SPE's. In one embodiment, the PMU is also configured to determine particular voltages at which power will be supplied to each of the SPE's, and to provide power to the SPE's at the identified voltages.

Various embodiments of the invention will be described below. Primarily, these embodiments will focus on implementations of architectures implemented within a digital integrated circuit. It should be noted that these embodiments are intended to be illustrative rather than limiting, and alternative embodiments may be implemented in other architectures, and may also be implemented in circuits whose components are not strictly limited to logic components (e.g., AND gates, OR gates, and the like.) Many such variations will be apparent to persons of ordinary skill in the art of the invention and are intended to be encompassed by the appended claims.

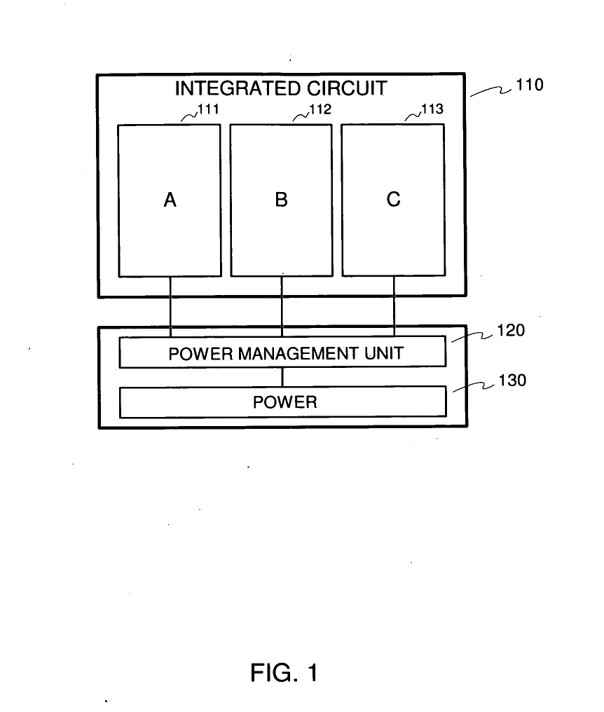

Referring to FIG. 1, illustrated is a functional block diagram in accordance with one embodiment. The diagram is of a system which includes an integrated circuit (IC) 110, a power management unit (PMU) 120, and a power source 130. In this figure, the IC is subdivided into three functional blocks/elements (A, B, C) 111, 112, 113. Functional blocks 111-113 may be any type of circuitry and, in one embodiment, they comprise subprocessor elements (SPE's.) It may be necessary or desirable to power down one of these functional blocks for any of a number of reasons, such as defects in the circuitry (making the SPE useless), a need to reduce power consumption, or a need to reduce thermal loading. When it is determined that an SPE is to be powered down, the PMU interrupts the power circuit for that SPE.

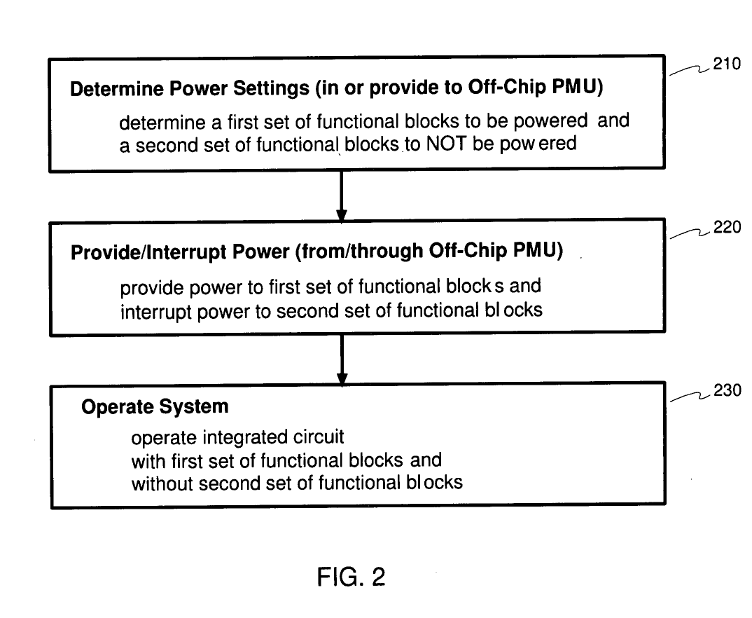

Each of blocks 111-113 is configured to be independently powered. Each of blocks 111-113 is therefore connected to PMU 120, which controls the power supplied to each of the blocks. In this embodiment, power from power source 130 is supplied to blocks 111-113 through PMU 120, although in other embodiments this may not be the case. The system operates basically as described in FIG. 2.

Referring to FIG. 2, a flow diagram illustrating the operation of a system in accordance with one embodiment is shown. The operation of the system begins with the determination of which functional blocks should be powered on and which should be powered off (210.) This determination may be made in a variety of ways, as will be described in more detail below. Once it is determined which of the functional blocks should receive power and which should not, the PMU takes appropriate action to either provide or inhibit power to each of the functional blocks (220.) The IC is then operated with the appropriate blocks powered (230).

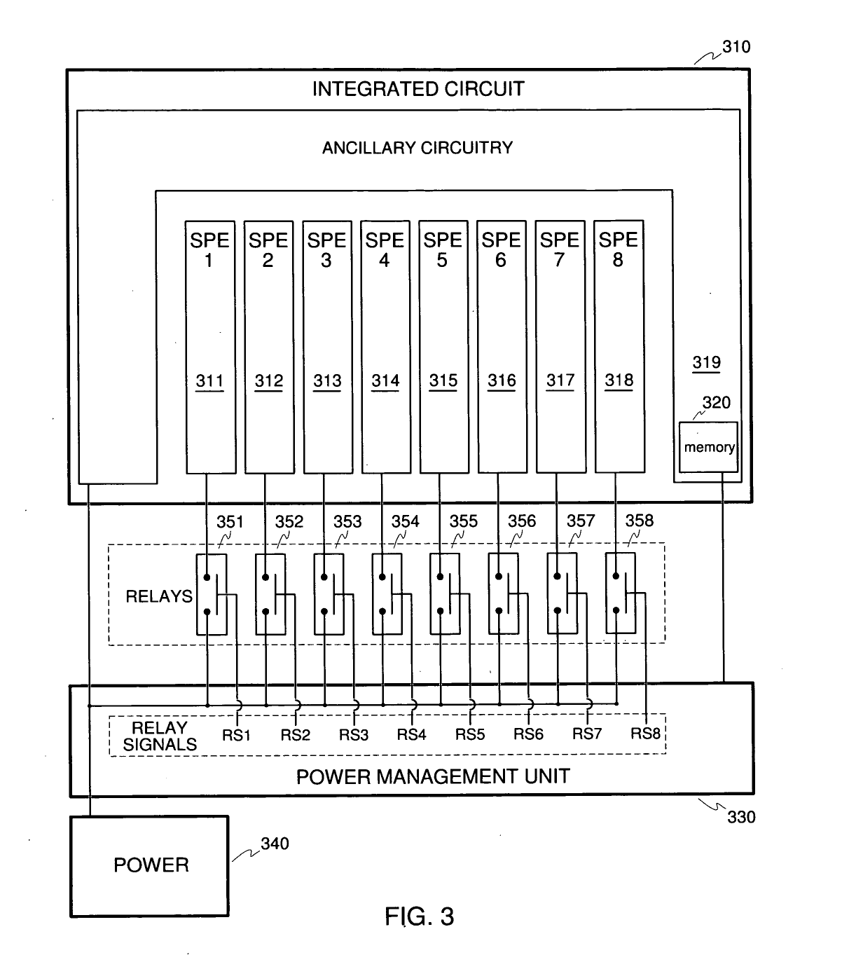

Referring to FIG. 3, a more detailed functional block diagram illustrating a system in accordance with one embodiment is shown. The system includes an integrated circuit (IC) 310, relays 351-358, a power source 340 and a power management unit (PMU) 330. In this figure, IC 310 is subdivided into nine regions comprising eight subprocessor elements (SPE's) 311-318 and a region 319 containing ancillary/supporting circuitry. Each of SPE's 311-318 is configured to be separately powered. That is, each SPE is separately coupled to power source 340 so that power can be provided to the SPE or inhibited, independently of any of the other SPE's and the ancillary region. The different regions (the SPE's and the ancillary region) are coupled to power source 340 through relays 351-358. Each SPE is separately coupled to power source through a corresponding one of relays 351-358. Thus, for example, opening relay 351 inhibits power to SPE 311, opening relay 352 inhibits power to SPE 312, and so on.

PMU 330 is constructed off the IC chip. By removing PMU 330 from the IC chip, the area of the chip that would otherwise have been occupied by the PMU is made available for other circuitry. This area may then be used for circuitry such as an additional SPE. In the diagram of FIG. 3, for instance, removal of PMU 330 from the IC may have made available space that was necessary to construct the eighth SPE (318). The yield improvement that is made possible by removing the PMU from the IC and adding a redundant SPE will be discussed in more detail.

Relays 351-358 are depicted in FIG. 3 as being off-chip. Taking the relays off the IC chip provides similar advantages to the removal of PMU 330 from the chip. Relays 351-358 may be part of PMU 330, or they may reside elsewhere. In either case, the relays are controlled by PMU 330 to either provide power to the corresponding SPE's or to inhibit power to them. When it is determined that a particular SPE is not needed, the PMU opens the associated relay. Otherwise, the relay is closed, and power is provided to the corresponding SPE. In the embodiment of FIG. 3, there is no relay between power source 340 and region 319, which contains ancillary/supporting circuitry, although it would be possible to include one.

In the embodiment of FIG. 3, PMU 330 may communicate with IC 310 aside from simply providing power to selected ones of SPE's 311-318. For example, the PMU may access memory 320 on the IC to determine which of SPE's 311-318 should be powered up. In one embodiment, memory 320 may be a read-only memory. If, for instance, it is determined during burn-in testing that the one of the SPE's is defective, that information may be stored in memory 320. Then, when the IC is booted up, PMU 330 may simply read memory 320 and set relays 351-358 accordingly. Alternatively, memory 320 may be writeable so that it can be altered during operation of the IC. In other embodiments, other variations may be implemented.

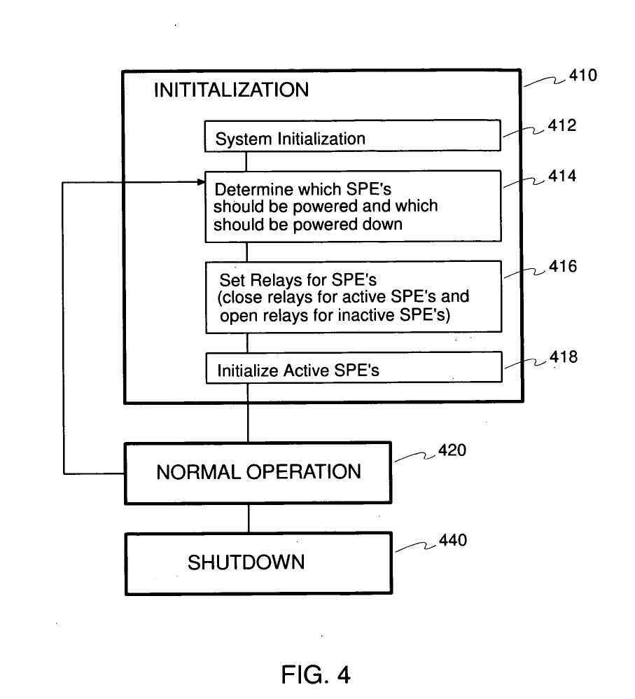

In one embodiment, the system diagramed in FIG. 3 operates basically as described in FIG. 4. Referring to FIG. 4, a flow diagram illustrating the operation of a system in accordance with one embodiment is shown. The operation of the system includes system initialization phase (410), a normal operation phase (420), and a shutdown phase (440).

During initialization phase 410, the PMU initializes (412) and begins operating. More specifically, it determines which of the SPE's will receive power and which will not (414). As noted above, this may be done by reading the information from an on-chip memory. When the set of SPE's that will be powered on has been determined, the PMU closes the relays for these SPE's and opens the relays corresponding to the SPE's that will not receive power (416). Once the relays have been set, power is provided to selected SPE's and inhibited to others, and the powered SPE's can be initialized (418). The IC can then begin operating (420) with the SPE's that are powered up. The SPE's that are not powered up obviously are not used.

It should be noted that FIG. 4 includes an arrow from 420 to 414. This arrow indicates that, in this particular embodiment, the system may periodically re-determine which of the SPE's should be powered up, and which should be powered down. This applies to systems in which non-defective SPE's may be powered down if they are not currently needed. Upon determining that a currently un-powered SPE is needed, the PMU can close the corresponding relay to provide power to the SPE, initialize the SPE, and then resume operation. (SPE's that are not powered because they are defective would not be subject to being powered up.) Similarly, when it is determined that a currently powered SPE is not needed, the PMU can stop operation of the SPE, open the corresponding relay to inhibit power to the SPE, and then resume operation.

It should also be noted that, although not explicitly depicted in FIG. 4, the PMU may provide power to the different SPE's at different voltages. Typically, an SPE will have a higher level of performance when operated at a higher voltage, and a lower level of performance when operated at a lower voltage. As a result of variations in manufacturing processes, each SPE may require a slightly different power supply voltage to operate at a desired level of performance. Under-performing SPE's may therefore require a slightly higher voltage, while over-performing SPE's may be able to operate at a slightly lower voltage. Thus, the step of determining which SPE's are to be powered up or down may include determining the specific voltages at which power will be provided to active (powered up) SPE's, and the step of setting the relays may include setting the voltages for the active SPE's. The voltage information for each SPE may, for example, be stored in the on-chip memory.

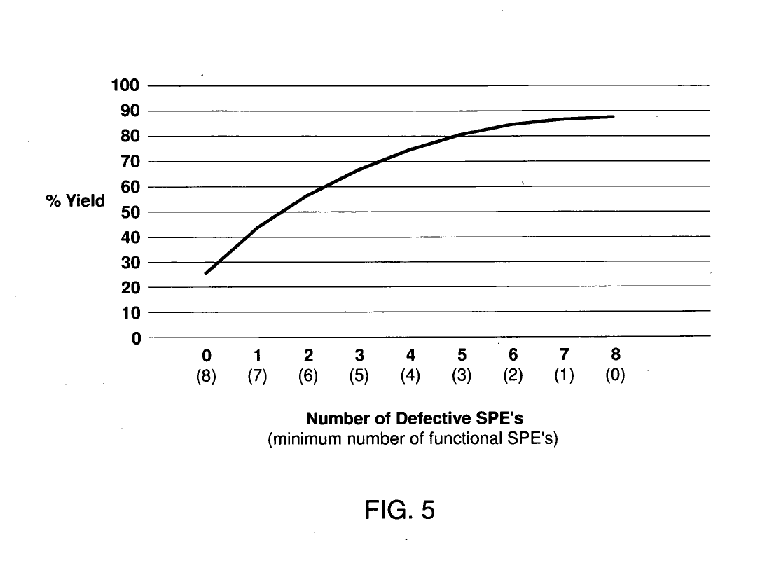

It is clear from the foregoing description that the amount of power used by an IC can be reduced by inhibiting power to a functional block rather than simply inhibiting a clock signal and thereby stopping the operation of the functional block. As noted above, however, embodiments of the present invention may also improve the yield of IC's into which they are incorporated. Hundreds of IC's may be produced on a single semiconductor wafer. Faulty design and manufacturing processes, as well as defects in the wafer itself, lead to defects in some of the IC's. The number of the IC's on the wafer that are usable is referred to as the yield. Some efforts to improve the yield focus on the reduction of the defects that arise in the manufacturing process. It is also possible to improve the yield by making the design of the IC flexible. That is, the IC can be designed to accommodate some defects, so that some IC's that have defects are usable and do not have to be discarded. One such design method involves providing redundant functional blocks in the IC so that, if a functional block includes a defect, a redundant functional block may be used in its place. Referring to FIG. 5, a diagram illustrating the percentage yield of an exemplary multiprocessor IC as a function of how many SPE's are defective is shown. It can be seen that the yield is very low (approximately 25%) if only IC's with no defective SPE's are usable. If one or more defective SPE's can be allowed, the yield increases. For example, if a single defective SPE is acceptable, the yield increases to approximately 45%. Thus, if one additional (redundant) SPE can be incorporated into the IC design, the yield of the exemplary IC could be increased from 25% to 45%.

The impact of embodiments of the present invention on the yield of the IC arises from the fact that the PMU is external to the IC. Because the PMU does not take up any space in the IC, the area of the IC is less than a similar system in which the PMU is on-chip. Then, the yield can be increased by manufacturing more of the IC's on a semiconductor wafer, or by using the space that would have been occupied by the PMU for a redundant functional block (e.g. an SPE.)

In the first scenario (manufacturing more IC's on the wafer), the yield simply increases with the number of IC's on the wafer. It is assumed that the same percentage of the IC's will be usable, so the increase in the yield will be proportional to the increase in the number of IC's on the wafer. For instance, if the removal of the PMU from the IC reduces the area of the IC by 5%, it will be possible to manufacture about 5% more IC's on the wafer. The yield will therefore increase by about 5%. Assuming as a baseline that 300 IC's can be manufactured on a single wafer, and that 25% of the IC's will be usable (corresponding to none of the SPE's being defective), the yield without removing the PMU from the IC will be 75 IC's. With the PMU off-chip, 5% more IC's can be manufactured, so the yield is 78-79 IC's.

In the second scenario, the increase in yield is even greater. In this case, the space made available by removing the PMU from the IC is used to add a redundant SPE to the IC design. In order to be conservative in the estimation of the yield improvement, it will be assumed that the addition of the SPE actually increases the size of the IC, so that less IC's can be manufactured on a single semiconductor wafer. In the baseline case above, the IC's would be usable if none of the SPE's were defective, resulting in a yield of 75 IC's. If the design includes one additional, redundant SPE, then the IC's will be usable even if one of the SPE's is defective. Assuming the additional SPE increases the size of the IC by about 10%, only 270 IC's can be manufactured on a wafer, but the percentage yield increases from about 25% to about 45%, so the yield is 121-122—an increase of 46-47 IC's.

While the foregoing description presents several specific exemplary embodiments, there may be many variations of the described features and components in alternative embodiments. For example, programmable interconnects can be used. Also, the elements needn't be limited to SPE's as in the described embodiments. The IC may be designed as a collection of standard cells, with relays/e-fuses/interconnects included with the needed electrical connections between the cells as part of a gate-level netlist. The design might also involve an entire chipset. Many other variations will also be apparent to persons of skill in the art of the invention upon reading the present disclosure.

Those of skill in the art will understand that information and signals may be represented using any of a variety of different technologies and techniques. For example, data, instructions, commands, information, signals, bits, and symbols that may be referenced throughout the above description may be represented by voltages, currents, electromagnetic waves, magnetic fields or particles, optical fields or particles, or any combination thereof. The information and signals may be communicated between components of the disclosed systems using any suitable transport media, including wires, metallic traces, vias, optical fibers, and the like.

Those of skill will further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Those of skill in the art may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with application specific integrated circuits (ASICs), field programmable gate arrays (FPGAs) or other logic devices, discrete gates or transistor logic, discrete hardware components, or any combination thereof designed to perform the functions described herein.

The steps of a method or algorithm described in connection with the embodiments disclosed herein may be embodied directly in hardware, in software (program instructions) executed by a processor, or in a combination of the two. Software may reside in RAM memory, flash memory, ROM memory, EPROM memory, EEPROM memory, registers, hard disk, a removable disk, a CD-ROM, or any other form of storage medium known in the art. Such a storage medium containing program instructions that embody one of the present methods is itself an alternative embodiment of the invention. One exemplary storage medium may be coupled to a processor, such that the processor can read information from, and write information to, the storage medium. In the alternative, the storage medium may be integral to the processor. The processor and the storage medium may reside, for example, in an IC.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein and recited within the following claims.

What is claimed is:

1. A system comprising:
an integrated circuit chip having circuitry formed thereon, wherein the circuitry includes two or more regions that are independently powered,
an off-chip power controller coupled to each of the two or more regions of the circuitry and configured to selectively power down one or more of the regions of the circuitry.

2. The system of claim 1, wherein at least one region comprises a processor core.

3. The system of claim 1, wherein the power controller is configured to provide power to a first one of the regions at a first voltage and to provide power to a second one of the regions at a second voltage which is different than the first voltage.

4. The system of claim 1, wherein the integrated circuit includes first circuitry configured to identify whether to supply power to each of the regions of the circuitry.

5. The system of claim 4, wherein the first circuitry includes a memory configured to store an indication of whether to power up each region of the circuitry.

6. The system of claim 4, wherein the first circuitry includes one or more electronic fuses configured to indicate whether to power up each region of the circuitry.

7. The system of claim 4, wherein the power controller is coupled to the first circuitry, wherein the first circuitry is configured to provide the indication of whether to power up each region of the circuitry to the power controller when the system boots up.

8. The system of claim 1, wherein each of the regions of the circuitry comprises a functional block of the system.

9. The system of claim 8, wherein one or more of the functional blocks is redundant.

10. The system of claim 9, wherein the system comprises a multiprocessor, and wherein at least one of the functional blocks comprises a processor core.

11. The system of claim 1, further comprising two or more relays, wherein each of the relays is coupled between a power source and a corresponding one of the regions of the circuitry, and wherein the power controller is coupled to each of the relays and configured to control the relays to connect a first set of the regions to a power source and to disconnect a second set of the regions from the power source.

12. A method comprising:
generating one or more control signals in an off-chip power controller, wherein the control signals define a first set of regions of circuitry on an integrated circuit chip to be powered on and a second set of regions of circuitry on the integrated circuit chip to be powered off;
providing power to the first set of regions of circuitry on the integrated circuit chip and inhibiting power to the second set of regions of circuitry on the integrated circuit chip in accordance with the control signals.

13. The method of claim 12, wherein at least one region of the circuitry comprises a processor core.

14. The method of claim 12, wherein providing power to the first set of regions of circuitry on the integrated circuit chip comprises providing power to at least one of the regions of circuitry at a first voltage and providing power to a at least one of the regions of circuitry at a second which is different than the first voltage.

15. The method of claim 12, further comprising identifying regions of the circuitry to be powered on and regions of the circuitry to be powered off before generating the control signals.

16. The method of claim 15, wherein identifying regions of the circuitry to be powered on and off comprises reading a memory that stores an indication of whether to provide power to each region of the circuitry.

17. The method of claim 15, wherein identifying regions of the circuitry to be powered on and off comprises the power controller querying on-chip circuitry for the indication of whether to power up each region of the circuitry during boot-up procedures.

18. The method of claim 12, wherein providing power to the first set of regions of circuitry on the integrated circuit chip and inhibiting power to the second set of regions of circuitry on the integrated circuit chip in accordance with the control signals comprises providing the control signals to a plurality of relays, wherein each of the relays is coupled between a power source and a corresponding one of the regions of the circuitry, and wherein the control signals are configured to control the relays to connect the first set of regions of circuitry to a power source and to disconnect the second set of the regions of circuitry from the power source.

19. The method of claim 12,
wherein the integrated circuit includes multiple functional blocks, one or more of which are redundant,
the method further comprising
determining whether any of the redundant functional blocks are defective,
inhibiting power to one or more of the redundant functional blocks, wherein the redundant functional blocks to which power is inhibited include ones of the redundant functional blocks which are determined to be defective,
providing power to the remainder of the functional blocks, and
operating the integrated circuit with ones of the functional blocks to which power is provided.

20. A method comprising:
constructing an integrated circuit having multiple functional blocks, wherein one or more of the functional blocks are redundant;
determining whether any of the redundant functional blocks are defective;
inhibiting power to one or more of the redundant functional blocks, wherein the redundant functional blocks to which power is inhibited include ones of the redundant functional blocks which are determined to be defective;
providing power to the remainder of the functional blocks; and
operating the integrated circuit with ones of the functional blocks to which power is provided.
